(19) United States
(12) Patent Application Publication
(10) Pub. No.: US 2010/0140806 A1
(43) Pub. Date: Jun. 10, 2010

(54) Method for Forming Super Contact in Semiconductor Device

(76) Inventor: Sang Chul KIM, Eumseong-gun (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/629,000

(22) Filed: Dec. 1, 2009

(30) Foreign Application Priority Data
Dec. 4, 2008 (KR) 10-2008-0122538

(51) Int. Cl. H01L 23/485; H01L 21/768

(52) U.S. Cl. 257/773; 438/660; 257/E21.585; 257/E23.019

(57) ABSTRACT

A method for forming a super contact in a semiconductor device is disclosed. The method enables forming a barrier film selectively on the silicon substrate, leaving the metal contact exposed for perfect isolation of the metal pad from the silicon substrate after formation of the super contact.

### CROSS REFERENCE TO RELATED APPLICATION

This application claims the benefit of Korean Patent Application No. 10-2008-0122538, filed on Dec. 4, 2008, which is hereby incorporated by reference as if fully set forth herein.

### BACKGROUND OF THE DISCLOSURE

1. Field of the Disclosure

The present invention relates to semiconductor devices, and more particularly, to a method for forming a super contact in a semiconductor device.

2. Discussion of the Related Art

A related art CMOS image sensor (CIS) is provided with photodiodes in a silicon substrate, and a multi-layered insulating film on the silicon substrate, which has multiple layers of metal lines therein.

Generally, the CMOS image sensor has no problem in reproduction of an image in a case of a VGA class image sensor. However, if a number of pixels increases over 2M, the size of the pixels are reduced, thereby decreasing the light quantity incident on the photodiode, making sensitivity of the CMOS image sensor relatively poor.

In order to address the above problem, backside illumination is suggested, in which a backside of a wafer is machined thin for illumination of the wafer from the backside of the wafer. In the backside illumination, metal lines are also provided on the photodiodes for illumination of the backside of the silicon substrate.

In order to fabricate a device structure in which the backside of the silicon substrate is machined thin like the backside illumination, the backside of the silicon substrate must be grounded after a wafer or sheet of glass is attached to a front side of the silicon substrate.

Moreover, to connect a lead for fabrication of a package, a super contact process can be used to connect a metal line to the backside of the silicon substrate.

FIG. 1 illustrates a cross-section for describing a related art process for forming a super contact. The related art process for forming a super contact will be described.

Referring to FIG. 1, a deep trench is formed in a wafer, and a super contact metal is filled in the trench.

Then, the wafer is turned over, and a portion of the silicon substrate is removed, to form a metal contact 3 projected from a surface of the silicon substrate 1. The metal contact 3 projects from a surface of the silicon substrate 1 for enhancing adhesion to a metal pad 5.

Then, the metal pad 5 is formed for electric connection to the metal contact 3. The metal pad 5 is in contact with the metal pad 3 only, and if the metal pad 5 is in contact with the silicon substrate 1, a problem takes place, in which metal ions diffuse from the metal pad 5 to the silicon substrate 1.

In order to prevent the metal ions of the metal pad 5 from diffusing to the silicon substrate 1, a barrier oxide 4 is deposited on an entire surface of the substrate before formation of the metal pad 5. Then, the barrier oxide 4 is removed from a portion of the metal contact 3, and the metal pad 5 is formed at the portion having the barrier oxide 4 removed therefrom.

In this instance, the related art process cannot remove the barrier oxide 4 only from the metal contact 3 selectively. That is, as shown, a larger portion of the barrier oxide 4 is removed than the area of the metal contact 3, to form the barrier oxide 4 which exposes a portion of the substrate 1. Consequently, since the width/area from which the barrier oxide is removed is greater than the width/area of the metal contact 3, a contact surface A to the silicon substrate is formed after formation of the metal pad 5 on the portion from which the barrier oxide 4 is removed, causing the problem of diffusion of the metal ions from the metal contact 3 to the silicon substrate 1 through the contact surface A. Thus, due to failure of perfect isolation of the metal pad 5 from the silicon substrate 1, the related art fails to solve the problem of diffusion of the metal ions to the silicon substrate 1.

### SUMMARY OF THE DISCLOSURE

Accordingly, the present invention is directed to a method for forming a super contact in a semiconductor device.

An object of the present invention is to provide a method for forming a super contact in a semiconductor device which enables perfect isolation of a metal pad electrically connected to a super contact in the silicon substrate at the time the metal pad is formed, and after formation of the super contact.

Another object of the present invention is to provide a method for forming a super contact in a semiconductor device which enables formation of a barrier film on a silicon substrate around a metal contact selectively for perfect isolation between a metal pad and the silicon substrate.

Additional advantages, objects, and features of the disclosure will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve these objects and other advantages and in accordance with the purpose(s) of the invention, as embodied and broadly described herein, a method for forming a super contact may include the steps of forming a metal contact on a silicon substrate, the metal contact projecting from the surface of a silicon substrate, forming a thermal oxide film on the surface of the silicon substrate, leaving the metal contact exposed, and forming a metal pad electrically connected to the metal contact on an upper surface of the metal contact and a portion of an upper surface of the thermal oxide film adjacent to the metal contact.

Preferably, the step of forming a metal contact comprises forming a deep trench or hole in the silicon substrate, filling a metal in the trench or hole, and etching an opposite side of the silicon substrate so that the metal contact projects from the surface of the silicon substrate.

Preferably, the method may further include the step of washing an upper side of the metal contact after formation of the thermal oxide film. The step of washing may include plasma treating a thin oxide film on the metal contact (that may have been formed at the time of forming the thermal oxide film) with ions of inert element to remove the thin film, and reforming a surface of the metal contact by heat treatment in a reducing (e.g., hydrogen (H₂)) environment or by plasma treatment with a reducing gas (e.g., hydrogen (H₂)). Preferably, the thermal oxide film has a thickness of 50˜500 Å.

The step of forming a thermal oxide film may include subjecting the silicon substrate to heat treatment in an oxidizing (e.g., oxygen (O₂)) environment to oxidize the surface of the silicon substrate. The heat treatment can be performed at 300˜800° C.

Another aspect of the present invention is to provide a metal contact in a silicon substrate, the metal contact projecting from a surface of the silicon substrate; a thermal oxide film on the surface of the silicon substrate, through which the metal contact is exposed; and a metal pad electrically connected to the metal contact, on or over an upper surface of the metal contact and an upper surface of the thermal oxide film adjacent to the metal contact.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle(s) of the disclosure. In the drawings:

FIG. 1 illustrates a cross-section for describing a related art process for forming a super contact.

FIGS. 2A to 2E illustrate cross-sections showing the steps of a method for forming a super contact in accordance with various embodiments of the present invention.

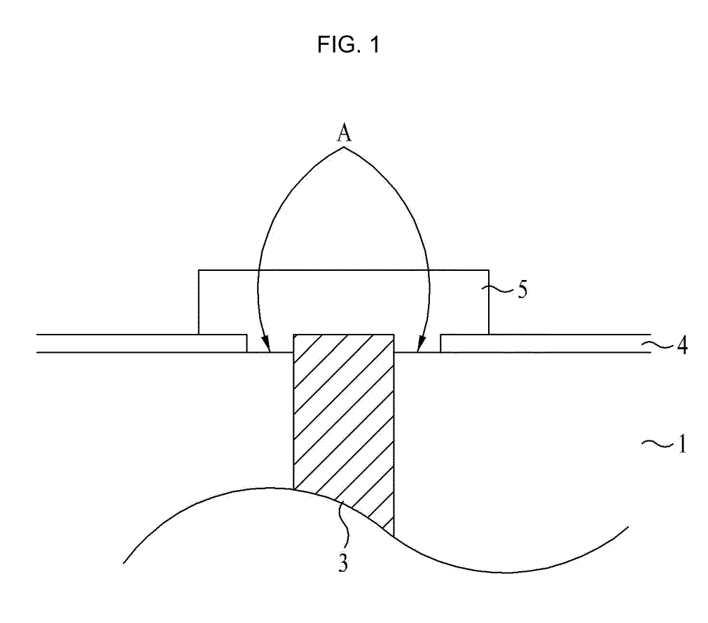

### DESCRIPTION OF SPECIFIC EMBODIMENTS

Reference will now be made in detail to the specific embodiments of the present invention, examples of which are illustrated in the accompanying drawings. Wherever possible, the same reference numbers will be used throughout the drawings to refer to the same or like parts.

A system and operation of the present invention shown in drawings and described with reference thereto is described according to at least one embodiment. However, the description does not limit a technical aspect and essential system and operation of the present invention.

A method for forming a super contact in accordance with various embodiments of the present invention will be described in detail with reference to the attached drawings.

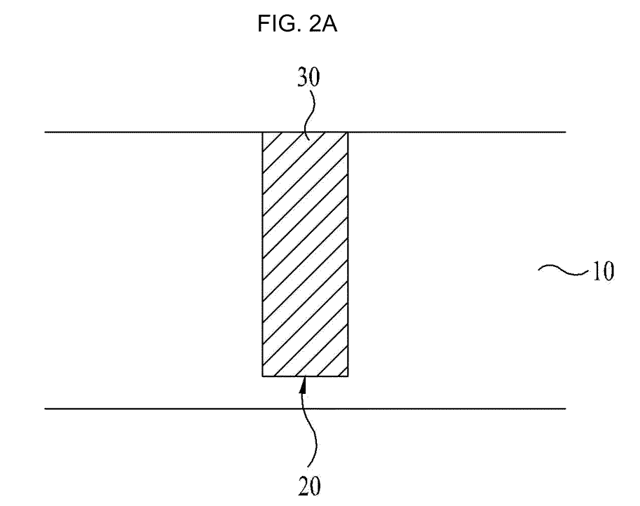

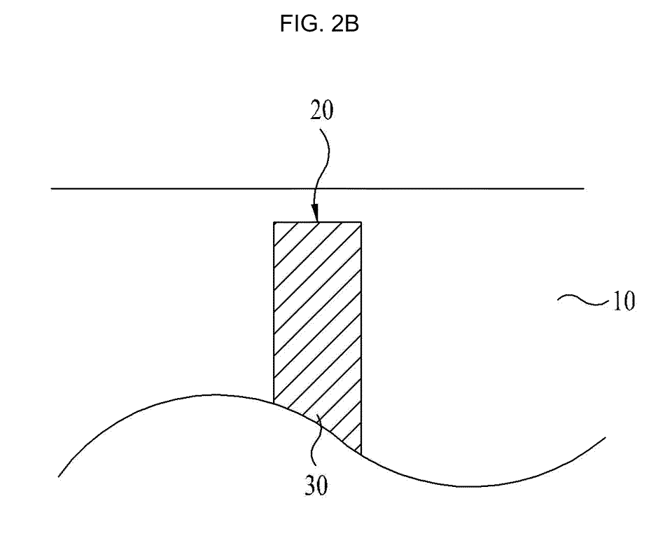

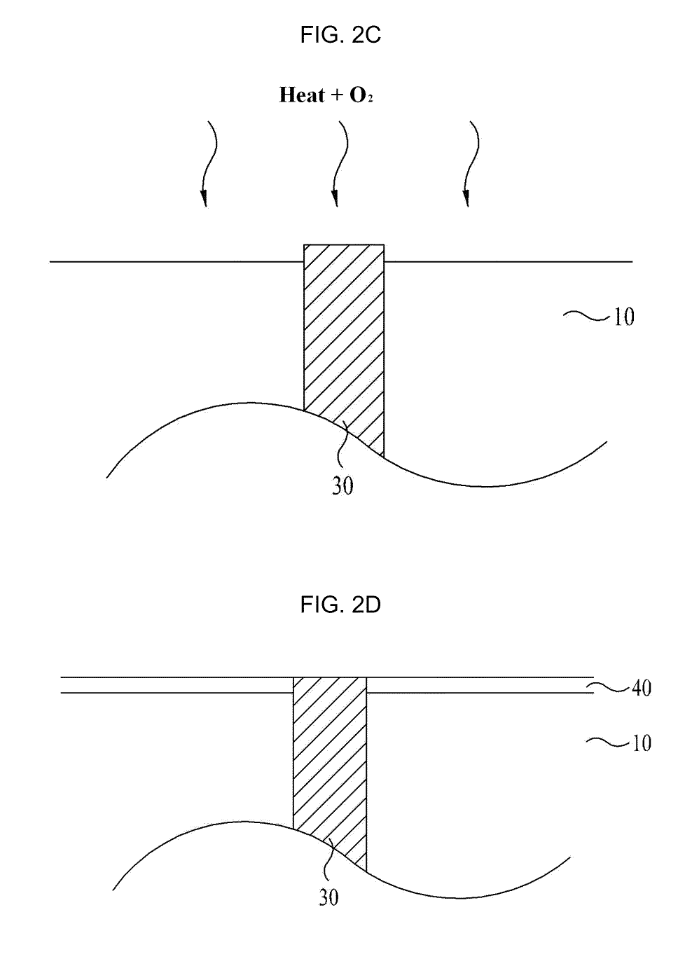

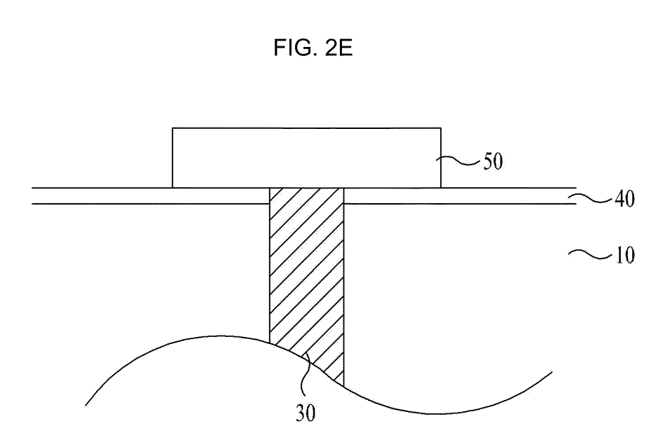

FIGS. 2A to 2E illustrate cross-sections showing the steps of a method for forming a super contact in accordance with various embodiments of the present invention.

Referring to FIG. 2A, a deep trench or hole 20 is formed in a silicon substrate 10, and the deep trench or hole 20 is filled with a metal to form a metal contact 30 in the silicon substrate 10. The metal may be selected from tungsten, copper, aluminum, an aluminum alloy (e.g., with one or more of silicon, titanium and copper), etc. Prior to filling the trench or hole 20 with metal, one or more liner and/or barrier layers may be deposited in the trench or hole 20. The liner and/or barrier layers may be selected from titanium, titanium nitride, tantalum, tantalum nitride, and laminates thereof (e.g., a titanium/titanium nitride bilayer, a tantalum/tantalum nitride bilayer, etc.). Following deposition of metal into the deep trench or hole 20, the excess metal outside the deep trench or hole 20 (e.g., on the substrate 10) can be removed by chemical mechanical polishing (CMP).

Then, the silicon substrate 10 is turned over, to expose the side of the substrate 10 opposite to the side in which the deep trench or hole 20 was formed. FIG. 2B shows the silicon substrate 10 turned over thus, with the backside of the wafer exposed upwards.

Referring to FIG. 2C, the silicon substrate 10 is etched such that the metal contact 30 formed by filling the trench 20 projects from a surface of the silicon substrate 10. The silicon substrate 10 may etched by any known etch chemistry that selectively etches silicon over the metal of the contact 30, such as dry (plasma) etching using a (hydro) fluorocarbon gas as an etchant. From 30 to 2000 Å (or any range of values therein, such as 50 to 1000 Å) of the silicon substrate 10 may be etched. The metal contact 30 projects from the surface of the silicon substrate 10 for enhancing adhesion to a subsequently formed metal pad.

Referring to FIG. 2D, the silicon substrate 10 is subjected to thermal treatment in an oxidizing environment to oxidize the surface of the silicon substrate 10, to form a thermal oxide film 40 that is a barrier film only on the surface of the silicon substrate 10. The oxidizing environment may include known oxidant gases, such as oxygen (O₂), ozone (O₃), nitrous oxide (N₂O), nitrosyl oxide (NO), nitric oxide (NO₂), etc., and may further include inert and optionally a carrier gas such as nitrogen (N₂), helium, neon, argon, etc. The heat treatment can be performed at 300˜800° C.

The thermal treatment in the oxidizing environment makes an oxygen source (e.g., O₂) react with silicon (Si) of the silicon substrate 10 to form a thermal oxide film 40 of SiO₂, as shown in FIG. 2C. The thermal oxide film 40 may contain some amount of nitrogen, without adverse effects. The thickness of the thermal oxide film 40 may be about equal to the thickness of the silicon substrate 10 removed in the etching step shown in FIG. 2C.

Since the thermal oxide film 40 is formed by the reaction of oxygen (O₂) with silicon, there is no exposed area of the surface of the substrate 10 around the metal contact 30, eventually preventing the metal pad 50 formed later from diffusing to the silicon substrate 10.

After formation of the thermal oxide film 40, the metal contact 30 may also have a thin oxide film (not shown) formed thereon.

Accordingly, an upper side of the metal contact 30 may be subjected to a washing step after formation of the thermal oxide film 40.

The washing step will be described in detail. The thin oxide film (not shown) that may be formed on the metal contact 30 at the time of formation of the thermal oxide film is removed by plasma treatment with ions of an inert element, such as argon (Ar), helium (He), or neon (Ne) (e.g., by sputter etching).

Subsequently, in exemplary embodiments, heat treatment is performed in a reducing environment or by plasma treatment with a reducing gas to reform the upper surface of the metal contact 30. The reducing environment may include one or more gases such as hydrogen (H₂), nitrogen (N₂), a silane (e.g., SiH₄ or Si₂H₆), etc., preferably including hydrogen. The reducing gas may include one or more gases such as hydrogen (H₂), nitrogen (N₂), a silane (e.g., SiH₄ or Si₂H₆), etc. (preferably hydrogen), and optionally a carrier gas such as helium, neon, argon, etc. In some embodiments, formation of a metal nitride and/or silicide on the surface of contact 30 does not adversely affect the performance of the contact 30 and pad 50.

The thermal oxide film 40 may be formed before the washing step, or after performing the washing step selectively In various embodiments of the present invention, the thermal oxide film 40 has a thickness of 50 to 500 Å.

Referring to FIG. 2E, the thermal oxide film 40 is formed only on the backside surface of the silicon substrate 10, leaving the metal contact 30 exposed. The metal pad 50 is electrically connected to the metal contact 30 by forming the metal pad 50 on an upper surface of the metal contact 30 and at least a portion of the thermal oxide film 40 adjacent to the metal contact 30. The metal pad 50 may be formed by blanket deposition of one or more adhesive, conductive barrier and/or bulk metal layers, such as titanium, titanium nitride, and aluminum or an aluminum alloy (as described herein).

The present invention applies heat in an oxidizing environment to induce oxidation of the surface of the silicon substrate 10, to form a barrier (e.g., the thermal oxide film 40) only on the surface of the silicon substrate 10. Thus, the thermal oxide film 40 may form a barrier film, leaving the metal contact 30 exposed, and isolating the metal pad 50 from the silicon substrate 10, perfectly.

The perfect isolation of the metal pad 50 from the silicon substrate 10 at the time of formation of the metal pad 50, which is to be connected to the super contact, provides formation of no contact between the surfaces of the metal pad 50 and the silicon substrate 10. Accordingly, no diffusion of metal ions from the metal contact 30 to the silicon substrate 10 can occur.

More specifically, the induction of oxidation of the surface of the silicon substrate 10 by applying heat thereto in the oxygen (O₂) environment permits forming the thermal oxide film 40 only on the surface of the silicon substrate 10. Accordingly, the metal pad 50 can be simply isolated from the silicon substrate 10 perfectly without additional complicated steps.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method of forming a contact, comprising:
forming a metal contact in a silicon substrate, the metal contact projecting from a surface of the silicon substrate;
forming a thermal oxide film on the surface of the silicon substrate, leaving the metal contact exposed; and
forming a metal pad electrically connected to the metal contact on or over an upper surface of the metal contact and an upper surface of the thermal oxide film adjacent to the metal contact.

2. The method as claimed in claim 1, wherein forming the metal contact comprises:
forming a deep trench or hole in the silicon substrate,
filling a metal in the trench or hole, and
etching a surface of the silicon substrate opposite to that in which the trench or hole is formed, such that the metal contact projects from the opposite surface of the silicon substrate.

3. The method as claimed in claim 1, further comprising washing an upper side of the metal contact after forming the thermal oxide film.

4. The method as claimed in claim 3, wherein washing of the upper side of the metal contact comprises:
plasma treating a thin oxide film on the metal contact with ions of an inert element to remove the thin oxide film, and
reforming a surface of the metal contact by heat treatment in a reducing environment or by plasma treatment with a reducing gas.

5. The method as claimed in claim 1, wherein the thermal oxide film has a thickness of 50˜500 Å.

6. The method as claimed in claim 1, wherein forming the thermal oxide film comprises subjecting the silicon substrate to heat treatment in an oxygen environment to oxidize the surface of the silicon substrate.

7. The method as claimed in claim 6, wherein the heat treatment is performed at 300˜800° C.

8. The method as claimed in claim 1, wherein the thermal oxide film comprises a SiO₂ layer.

9. The method as claimed in claim 3, wherein forming the thermal oxide film occurs before washing the metal contact.

10. The method as claimed in claim 3, further comprising forming the thin oxide film on the metal contact during formation of the thermal oxide film.

11. The method as claimed in claim 4, wherein removing the thin oxide film comprises plasma treatment with said inert element ions.

12. The method as claimed in claim 4, wherein the inert element ions are selected from the group consisting of argon, helium, neon and krypton.

13. The method as claimed in claim 1, further comprising forming the metal pad on upper surface of the metal contact and the upper surface of the thermal oxide film adjacent to the metal contact.

14. The method as claimed in claim 1, wherein forming the thermal oxide film on the upper surface of the silicon substrate isolates the metal pad from the silicon substrate.

15. A semiconductor device comprising:
a metal contact in a silicon substrate, the metal contact projecting from a surface of the silicon substrate;
a thermal oxide film on the surface of the silicon substrate, through which the metal contact is exposed; and
a metal pad electrically connected to the metal contact, on or over an upper surface of the metal contact and an upper surface of the thermal oxide film adjacent to the metal contact.

16. The semiconductor device as claimed in claim 15, wherein the thermal oxide film isolates the metal pad from the silicon substrate.

17. The semiconductor device as claimed in claim.
